(19) United States
(12) Patent Application Publication
(10) Pub. No.: US 2015/0108630 A1
(43) Pub. Date: Apr. 23, 2015

(54) ELECTRONIC DEVICE, ELECTRONIC APPARATUS, AND METHOD FOR MANUFACTURING ELECTRONIC DEVICE

(71) Applicant: FUJITSU LIMITED, Kawasaki-shi (JP)

(72) Inventors: Takaharu IZUNO, Kawasaki (JP); Osamu SAITO, Kawasaki (JP); Mitsuaki HAYASHI, Kawasaki (JP); Kenji JOKO, Yokohama (JP); Hideaki MATSUMOTO, Yokohama (JP); Minoru FUJII, Kawasaki (JP)

(73) Assignee: FUJITSU LIMITED, Kawasaki-shi (JP)

(21) Appl. No.: 14/459,384

(22) Filed: Aug. 14, 2014

(30) Foreign Application Priority Data
Oct. 22, 2013 (JP) 2013-219674

(51) Int. Cl. H01L 23/34; H01L 21/50

(52) U.S. Cl. CPC H01L 23/34; H01L 21/50
USPC 257/713; 438/122

(57) ABSTRACT

An electronic device includes a first circuit board; a heat sink fixed to the first circuit board to form a cavity between the heat sink and the first circuit board; and a plurality of electronic components fixed to a surface of the heat sink facing the first circuit board inside the cavity, the plurality of electric components having heights different from each other, wherein each of the plurality of electronic components is electrically coupled to the first circuit board by a second circuit board and being different from the first circuit board.

### CROSS-REFERENCE TO RELATED APPLICATION

This application is based upon and claims the benefit of priority of the prior Japanese Patent Application No. 2013-219674, filed on Oct. 22, 2013, the entire contents of which are incorporated herein by reference.

### FIELD

The embodiments discussed herein are related to an electronic device, an electronic apparatus, and a method for manufacturing an electronic device.

### BACKGROUND

Due to demands for higher-performance and smaller-size electronic apparatuses in recent years, the high density mounting of electronic components incorporated in electronic apparatuses has been advancing rapidly. To accomplish the higher density mounting, semiconductor chips are now more often surface-mounted as bare chips on a wiring board, that is, flip-chip mounted.

With the improvement in performance, flip-chip mounted semiconductor chips generate a larger amount of heat. Accordingly, a structure has been used in which a heat sink made of a material having high thermal conductivity such as copper is disposed above semiconductor chips with a thermal sheet (also referred to as a heat dissipation sheet or thermal conduction sheet) provided on top of the semiconductor chips, for example.

Meanwhile, plug-in unit (PIU) type electronic apparatuses in which multiple PIUs are housed in a casing have been used in applications such as information processing and information communication. Each PIU is a single printed board with multiple electronic components mounted thereon. As for the PIU type electronic apparatuses, techniques for suppressing increase in package area have been disclosed in which a single heat sink is disposed on all the multiple electronic components mounted on a PIU to cool the entire PIU, instead of individually disposing heat sinks on electronic components. Japanese Laid-open Patent Publication No. 4-188795, for example, has been disclosed as related art.

The heights of electronic components in a state of being mounted on a printed board may be different from each other. For example, when electronic components are of different types, their heights in the mounted state may be different. Even when electronic components are of the same type, their heights in the mounted state may vary due to the manufacturing tolerance. Accordingly, there is a possibility that it may be difficult to cool multiple electronic components by using a single heat sink.

### SUMMARY

According to an aspect of the invention, an electronic device includes a first circuit board; a heat sink fixed to the first circuit board to form a cavity between the heat sink and the first circuit board; and a plurality of electronic components fixed to a surface of the heat sink facing the first circuit board inside the cavity, the plurality of electric components having heights different from each other, wherein each of the plurality of electronic components is electrically coupled to the first circuit board by a second circuit board and being different from the first circuit board.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of an electronic apparatus;

FIG. 2 is a structural view illustrating an example of an electronic device in a first embodiment;

FIG. 3 is a perspective view illustrating a state of the electronic device illustrated in FIG. 2 without a heat sink mounted thereon;

FIG. 4 is a flowchart illustrating an example of a method for manufacturing a rigid-flexible board in the first embodiment;

FIG. 5 is a plan view illustrating a state after a glass epoxy board is attached in S101;

FIG. 6 is a perspective view illustrating a state of the electronic device illustrated in FIG. 2 with the heat sink mounted thereon;

FIG. 7 is a flowchart illustrating an example of a method for manufacturing the electronic device in the first embodiment;

FIGS. 8A and 8B are diagrams illustrating the example of the method for manufacturing the electronic device in the first embodiment (part 1);

FIGS. 9A and 9B are diagrams illustrating the example of the method for manufacturing the electronic device in the first embodiment (part 2);

FIG. 10 is a diagram illustrating an example of an electronic device in a second embodiment;

FIG. 11 is a diagram illustrating a modification of the electronic device in the second embodiment;

FIG. 12 is a structural view illustrating an example of an electronic device in a third embodiment;

FIGS. 13A and 13B are perspective views illustrating an example of electronic component modules to be mounted on the electronic device in FIG. 12;

FIG. 14 is a perspective view illustrating a state of the electronic device illustrated in FIG. 12 without the electronic component modules mounted thereon;

FIG. 15 is a perspective view illustrating a state of the electronic device illustrated in FIG. 12 with the electronic component modules mounted thereon;

FIG. 16 is a perspective view illustrating a state of the electronic device illustrated in FIG. 12 with a heat sink mounted thereon;

FIG. 17 is a structural view illustrating an example of an electronic device in a fourth embodiment;

FIGS. 18A and 18B are perspective views of the electronic device illustrated in FIG. 17; and

FIG. 19 is a diagram illustrating a modification of the electronic device in the first embodiment.

### DESCRIPTION OF EMBODIMENTS

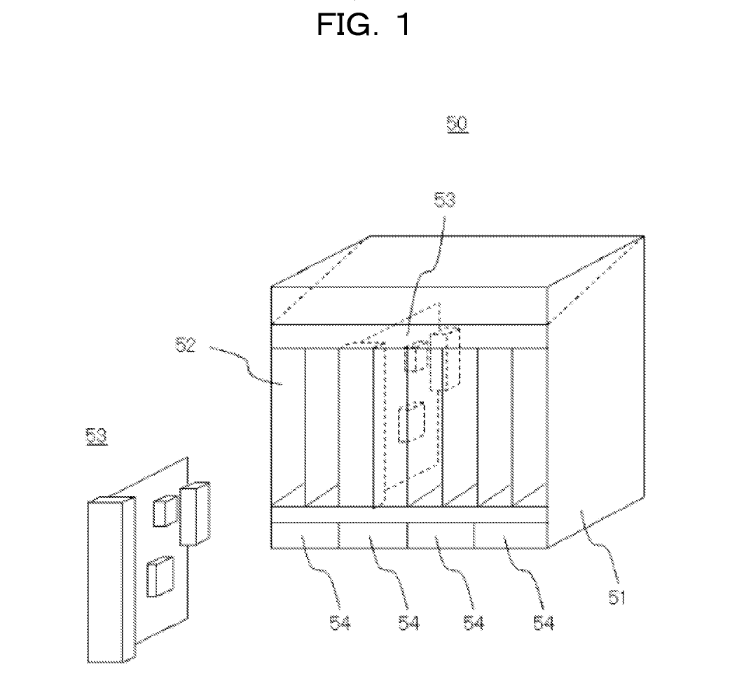

Hereinafter, embodiments are described in detail with reference to FIGS. 1 to 19.

FIG. 1 is a diagram illustrating an example of an electronic apparatus. An electronic apparatus 50 includes a casing 51, shelves 52, cooling units 54, and one or more PIUs 53. Each PIU 53 is an example of an electronic device. In FIG. 1, parts that are actually hidden are illustrated by dotted lines.

The electronic apparatus 50 has a structure in which one or more PIUs 53 are housed in multiple shelves 52 provided in the casing 51. Although one PIU 53 is housed in the electronic apparatus 50, multiple PIUs 53 are generally housed when the electronic apparatus 50 is used. Each PIU 53 is plug-in connected to connectors provided to the casing 51 side, and may therefore be detached and replaced when desired. A wiring board, or a back wiring board (BWB), is provided on the back surface of the casing 51. The BWB is electrically connected to the PIUs 53 by the connectors.

### First Embodiment

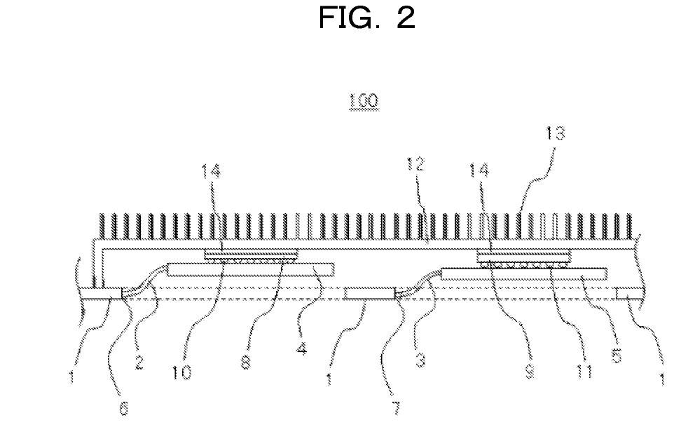

A first embodiment is described with reference to FIGS. 2 to 9.

FIG. 2 is a structural view illustrating an exemplary electronic device in the first embodiment. As illustrated in FIG. 2, an electronic device 100 includes: a first circuit board 1; second circuit boards 2 and 3 having flexibility and electrically coupled to the first circuit board 1; a third circuit board 4 electrically coupled to the second circuit board 2; and a third circuit board 5 electrically coupled to the second circuit board 3.

FIG. 2 illustrates an example of a so-called rigid-flexible board in which the first circuit board 1 and the third circuit boards 4 and 5 being rigid boards and the second circuit boards 2 and 3 being flexible boards are integrated. Specifically, the first circuit board 1 and the third circuit boards 4 and 5 are rigid boards which may be obtained via build-up formation of glass epoxy boards including wiring layers over the upper and lower sides of wiring layers of the second circuit boards 2 and 3.

Openings 6 and 7 are provided in the first circuit board 1. The second circuit board 2 extends from the inner surface of the opening 6, and the wiring layers of the second circuit board 2 are integrally buried in the first circuit board 1 and the third circuit board 4. The second circuit board 3 extends from the inner surface of the opening 7, and the wiring layers of the second circuit board 3 are integrally buried in the first circuit board 1 and the third circuit board 5.

As illustrated in FIG. 2, the electronic device 100 further includes an electronic component 8 and an electronic component 9. The electronic component 8 is disposed on the third circuit board 4 and electrically coupled to the third circuit board 4 by multiple solder bumps 10. The electronic component 9 is disposed on the third circuit board 5 and electrically coupled to the third circuit board 5 by multiple solder bumps 11. In the example of FIG. 2, the thickness of the electronic component 9 is greater than the thickness of the electronic component 8. Thus, the height of the electronic component 9 in the mounted state from the third circuit board 5 is greater than the height of the electronic component 8 in the mounted state from the third circuit board 4. The openings 6 and 7 are provided at such positions as to face the electronic components 8 and 9. Here, the height in the mounted state is defined as the height of the electronic component from the surface of the circuit board on which the electronic component is mounted.

A heat sink 12 is provided above the electronic components 8 and 9. The heat sink 12 is fixed to the first circuit board 1. By this fixing, a certain space capable of housing the electronic components 8 and 9 is formed between the heat sink 12 and the first circuit board 1. Inside this space, the electronic components 8 and 9 are fixed to the surface of the heat sink 12 facing the first circuit board 1. The heat sink 12 includes multiple heat dissipation fins 13. The heat dissipation fins 13 are provided to increase the surface area of the heat sink 12. The heat dissipation fins 13 may be formed through cutting work of the heat sink 12, for example.

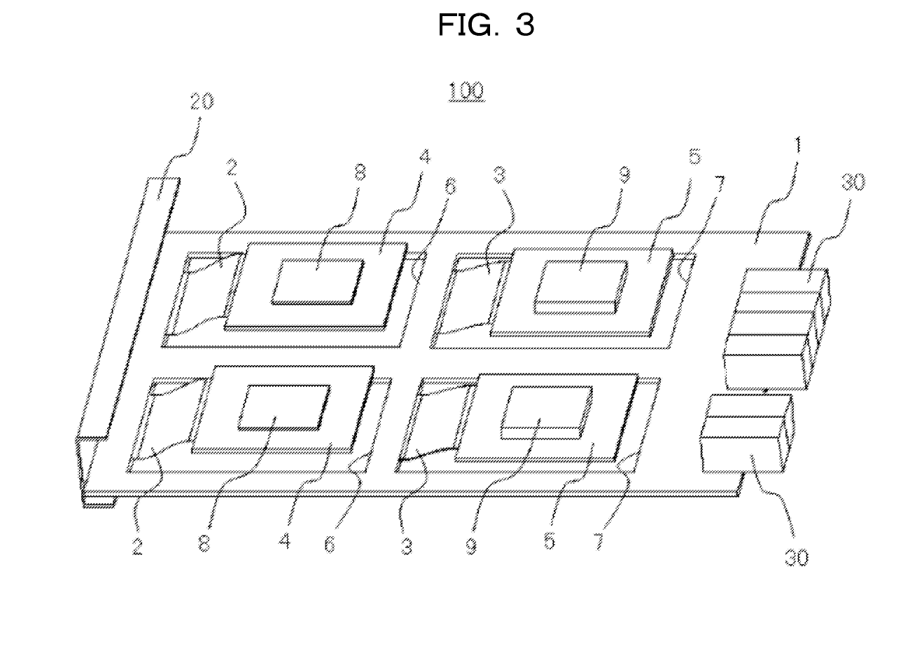

FIG. 3 is a perspective view illustrating a state of the electronic device 100 illustrated in FIG. 2 without the heat sink 12 mounted thereon. The electronic device 100 illustrated in FIG. 3 is an example of the PIUs. The electronic device 100 includes a face plate 20 and connectors 30 for electrically connecting the electronic device 100 to the BWB.

As illustrated in FIG. 3, the openings 6 and 7 are provided in the first circuit board 1 immediately under the third circuit boards 4 and 5, respectively. The area of each opening 6 is greater than the area of the corresponding third circuit board 4. In plan view of the first circuit board 1 seen from above, the second circuit boards 2 and the third circuit boards 4 are disposed within the openings 6 and do not overlap the first circuit board 1. Likewise, the area of each opening 7 is greater than the area of the corresponding third circuit board 5. In plan view of the first circuit board 1 seen from above, the second circuit boards 3 and the third circuit boards 5 are disposed within the openings 7 and do not overlap the first circuit board 1.

The first circuit board 1, the second circuit boards 2 and 3, and the third circuit boards 4 and 5 forming the rigid-flexible board may be manufactured by the following method, for example.

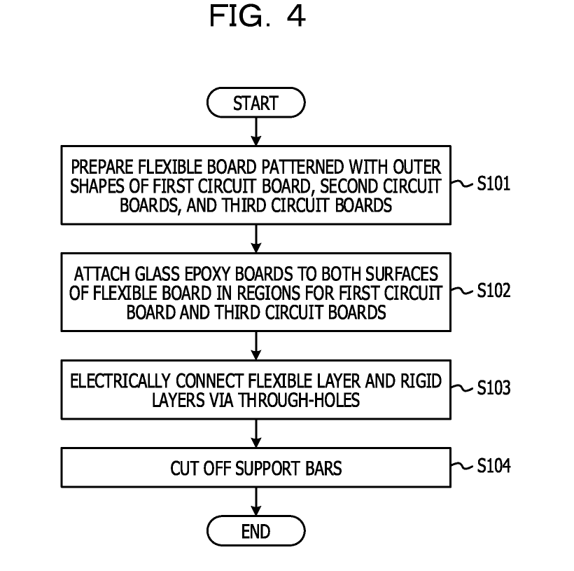

FIG. 4 is a flowchart illustrating an example of the method for manufacturing the rigid-flexible board in the first embodiment.

First, a flexible board is prepared which is patterned with the outer shapes of the first circuit board, the second circuit boards, and the third circuit boards (S101).

Then, glass epoxy boards (rigid layers) are attached to both surfaces of the flexible board (flexible layer) in regions for the first circuit board 1 and the third circuit boards 4 and 5 (S102).

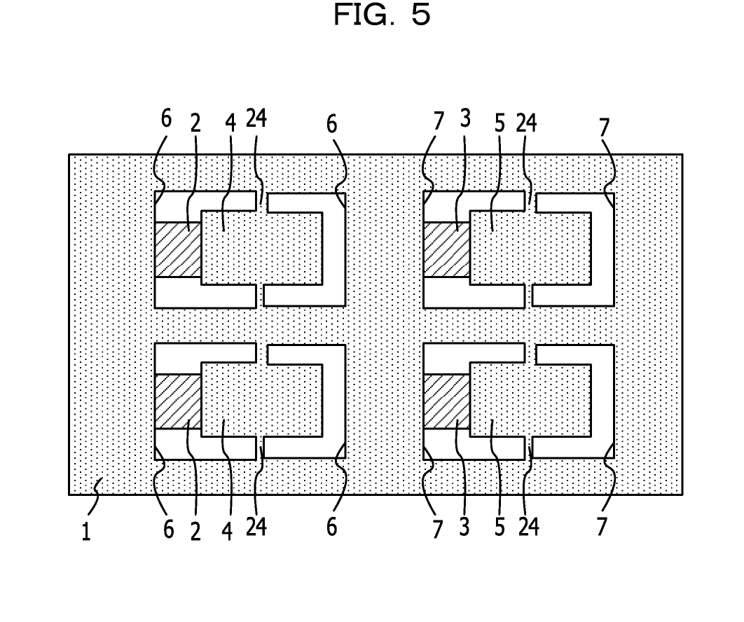

FIG. 5 is a plan view illustrating the state after the glass epoxy boards are attached in S101. It may be difficult to perform the attaching process since the glass epoxy boards to be attached at the positions of the third circuit boards 4 and 5 are in island shapes. Accordingly, as illustrated in FIG. 5, when attaching the glass epoxy boards, the glass epoxy board to be attached to the region for the first circuit board 1 and the glass epoxy boards to be attached to the regions for the third circuit boards 4 and 5 are connected to each other by support bars 24 as one integral body. These support bars 24 are formed by stacking the flexible board and the glass epoxy boards, as is done in the regions for the first circuit board 1 and the third circuit boards 4 and 5.

Thereafter, the flexible layer and the rigid layers are electrically coupled via through-holes (S103). As a result, the regions where the glass epoxy boards are attached are obtained as the first circuit board 1 and the third circuit boards 4 and 5, and the regions where the glass epoxy boards are not attached are obtained as the second circuit boards 2 and 3.

Thereafter, the support bars 24 are cut off (S104). By the process of S104, the region of the first circuit board 1 and the regions of the third circuit boards 4 and 5 may be isolated from each other.

By the method described above, the rigid-flexible board may be manufactured. The third circuit boards 4 and 5 are manufactured by the same process as the first circuit board 1 and therefore have the same layer structure as the first circuit board 1.

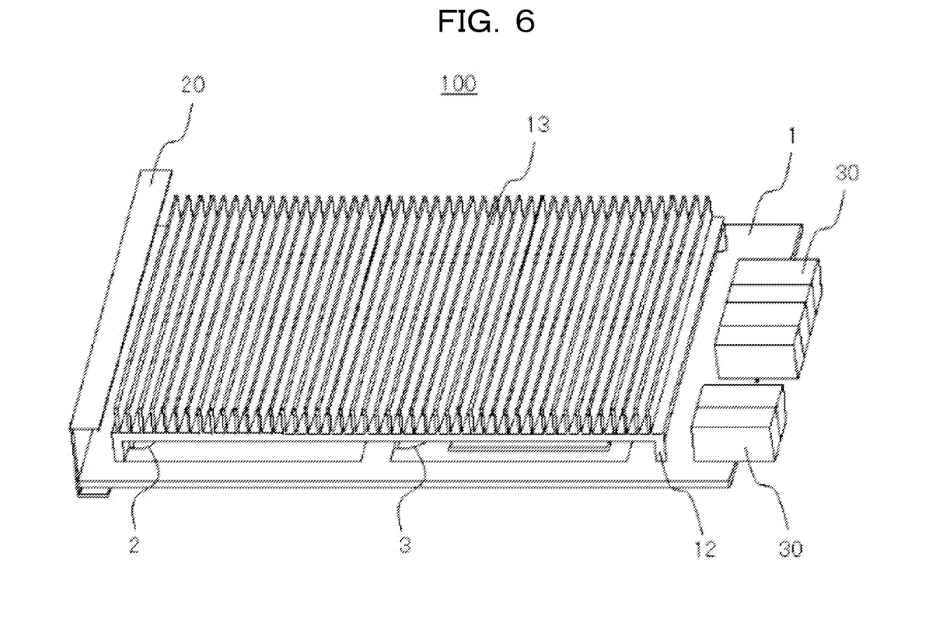

FIG. 6 is a perspective view illustrating a state of the electronic device 100 illustrated in FIG. 2 with the heat sink 12 mounted thereon. As illustrated in FIG. 6, the heat sink 12 covers the electronic components 8 and 9 from above the first circuit board 1. Here, the electronic components 8 and 9 are separated from each other in plan view seen in a direction from the heat sink 12 toward the first circuit board 1. The area of the heat sink 12 in plan view is smaller than that of the first circuit board 1, and the height of the heat sink 12 in the attached state is smaller than the height of the face plate 20. With this structure, the electronic device 100 may be housed in a shelf of the casing of the PIU-type electronic apparatus without interference.

Referring back to FIG. 2, the electronic components 8 and 9 are bonded to the heat sink 12 with a thermally conductive resin 14. By this structure, the electronic components 8 and 9 and the heat sink 12 are in thermal contact with each other. Further, the heat sink 12 is fixed to the first circuit board 1 with mechanical members such as screws, for example. Two second circuit boards 2 and 3 are illustrated in FIG. 2, and two second circuit boards 2 and two second circuit boards 3 are illustrated in FIG. 3. However, the numbers of second circuit boards are not limited to these numbers.

Details of each part of the electronic device 100 are described below.

In each of the first circuit board 1 and the third circuit boards 4 and 5, wiring patterns containing Cu are formed on both surfaces of a substrate of, for example, glass ceramic, glass epoxy, bismaleimide-triazine (BT) resin, or the like. Moreover, the wiring patterns are electrically coupled by via holes. In each of the third circuit boards 4 and 5, electrode pads are disposed as part of the wiring patterns at positions for the multiple solder bumps 10 and 11. The wiring patterns, the via holes, and the electrode pads are not illustrated in FIGS. 2 and 3. The first circuit board is sometimes called a motherboard, a mainboard, or the like. The second circuit boards are sometimes called a daughterboard, a subboard, or the like.

Each of the electronic components 8 and 9 is, for example, a semiconductor chip including a silicon substrate and an integrated circuit (IC) formed thereon. The semiconductor chip generates heat as the integrated circuit is powered during operation. As another example of the electronic components 8 and 9, it is possible to use, for example, a so-called semiconductor package manufactured by sealing (packaging) a semiconductor chip with sealing resin, ceramic, glass, or the like.

Each of the second circuit boards 2 and 3 has a structure in which a conductive foil (for example, Cu foil) to be used as wiring patterns is formed on a resin film of polyimide or the like (base film) with an adhesive layer interposed therebetween, and a region excluding external connection terminals is covered with a resin film of polyimide or the like (cover layer). The thickness of the base film is about 12 to 50 μm, for example. The total thickness of each of the second circuit boards 2 and 3 is about, 0.1 to 0.3 mm, for example. The second circuit boards 2 and 3 have flexibility because of the use of resin films, and are therefore easily deformable.

The heat sink 12 has the function of cooling the electronic components 8 and 9. The heat sink 12 may absorb heat generated from the electronic components 8 and 9, over a wide area through the thermally conductive resin 14 and dissipate the heat to ambient air. For the heat sink 12, a material containing Cu or Al and having a thickness of about 5 mm to 15 mm may be used, for example.

The thermally conductive resin 14 is a member used as a thermal interface material (TIM) that guides heat generated from the electronic components 8 and 9 to the heat sink 12. An adhesive or a thermal sheet made, for example, of a resin such as silicone, acrylic, or polyolefin may be used as the thermally conductive resin 14. Alternatively, a heat dissipation sheet containing a highly thermally conductive filler as a thermal conductor may be used as the thermally conductive resin 14. An elemental metal such as Au, Ag, Cu, Pt, Pd, Pb, Sn, Fe, Zn, Al, Cr, or Ti, for example, may be used as the filler. Alternatively, an alloy such as a Fe-Ni alloy, stainless steel, solder, beryllium copper, bronze, phosphor bronze, or brass, or electrically conductive particles obtained by performing treatment such as metal coating on the surfaces of particles of carbon, ceramic, or the like may be used as the filler.

Next, a method for manufacturing the electronic device 100 according to this embodiment is described.

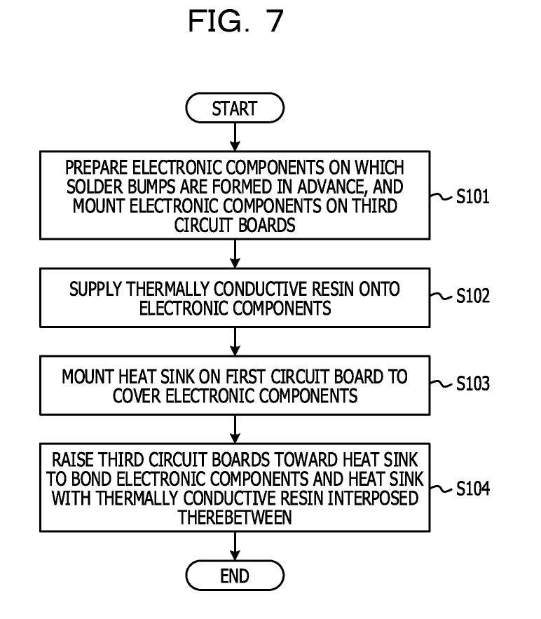

FIG. 7 is a flowchart illustrating an example of the method for manufacturing the electronic device 100 in the first embodiment.

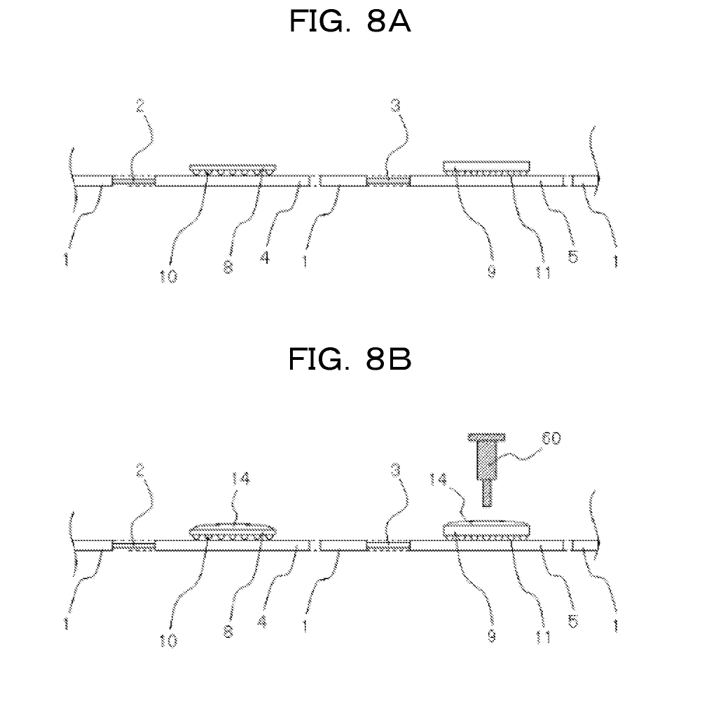

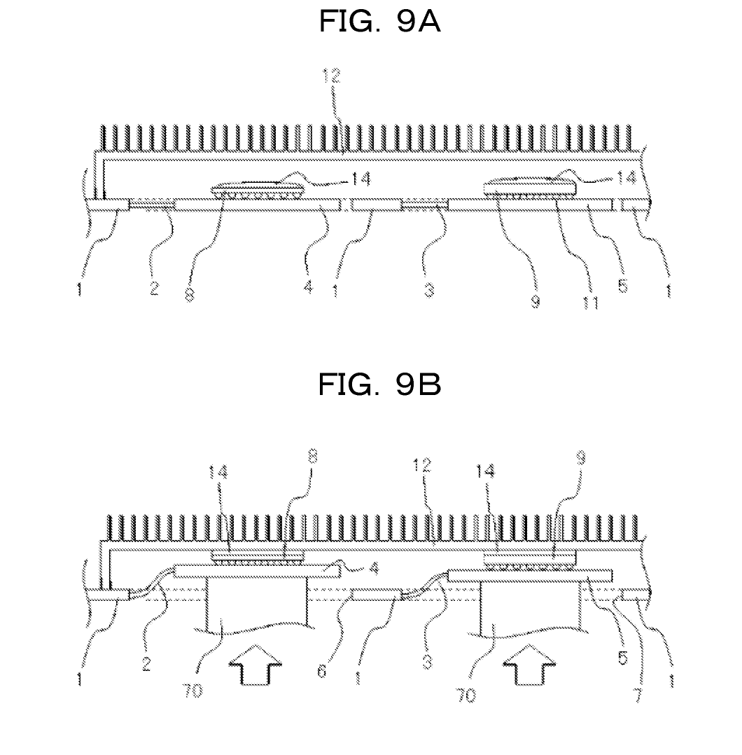

FIGS. 8A, 8B, 9A, and 9B are diagrams illustrating the example of the method for manufacturing the electronic device 100 in the first embodiment. In FIGS. 8A, 8B, 9A, and 9B, illustration of wires and via holes are omitted.

First, as illustrated in FIG. 8A, the electronic component 8 on which the solder bumps 10 are formed in advance is prepared. Then, the electronic component 8 is mounted on the third circuit board 4 (S201). The electronic component 8 may be mounted by, for example, a method such as controlled collapse chip connection (C4) using a flip-chip bonder. Similarly, the electronic component 9 on which the solder bumps 11 are formed in advance is prepared. Then, the electronic component 9 is mounted on the third circuit board 5. After the electronic components 8 and 9 are mounted, the gaps between the solder bumps 10 and between the solder bumps 11 may be filled with an underfill resin to protect or reinforce the soldered portions.

Then, as illustrated in FIG. 8B, the thermally conductive resin 14 is supplied onto the electronic components 8 and 9 by using a dispenser 60, for example (S202).

Thereafter, as illustrated in FIG. 9A, the heat sink 12 is mounted on the first circuit board 1 in such a way as to cover the electronic components 8 and 9 (S203). Here, the heat sink 12 is fixed to the first circuit board 1 by using mechanical members such as screws, for example. By this fixing, a certain space is formed between the first circuit board 1 and the electronic components 8 and 9. In this state, the electronic components 8 and 9 and the heat sink 12 are not yet bonded to each other.

Then, as illustrated in FIG. 9B, the third circuit boards 4 and 5 are raised toward the heat sink 12 by using pushing jigs 70, so that the electronic components 8 and 9 and the heat sink 12 are bonded to each other with the thermally conductive resin 14 interposed therebetween (S204). Here, the openings 6 and 7 are provided in the first circuit board 1. Thus, the electronic components 8 and 9 and the heat sink 12 may be bonded to each other with the thermally conductive resin 14 interposed therebetween by using the pushing jigs 70 inserted in the openings 6 and 7 to push the third circuit boards 4 and 5.

According to this embodiment, the second circuit boards 2 and 3 having flexibility are used to electrically connect the first circuit board 1 and the third circuit boards 4 and 5. Thus, by deforming the second circuit boards 2 and 3, it is possible to change the height levels of the third circuit boards 4 and 5 from the first circuit board 1 as desired while maintaining the electrical connection between the first circuit board 1 and the third circuit boards 4 and 5.

In a case where the thermally conductive resin 14 is a thermosetting resin, heat treatment is performed to thermally cure the thermally conductive resin 14 while a load is applied to the pushing jigs 70 toward the heat sink 12. The load to be applied to the heat sink 12 is preferably set such that the thermal resistance of the thermally conductive resin 14 is a minimum, and is about 0.25 Pa, for example. The heat treatment is performed by reflow and the reflow conditions are 195° C. and about 10 minutes, for example.

The structure illustrated in FIG. 2 is obtained when the bonding of the electronic components 8 and 9 and the heat sink 12 is complete.

Suppose a case where a single heat sink is mounted over multiple electronic components mounted on a circuit board and having height different from each other in the mounted state. In this case, the multiple electronic components may each be bonded to the single heat sink by setting the thickness of the thermally conductive resin differently for each electronic component. Here, the smaller the height of the electronic component in the mounted state, the larger the thickness of its thermally conductive resin is set. However, the thermal conductivity decreases as the thickness of the thermally conductive resin increases. Thus, there is a possibility that it may be difficult to sufficiently cool electronic components having small heights in the mounted state.

On the other hand, according to this embodiment, the electronic components 8 and 9 are moved upward from the first circuit board 1 while the electrical connection between the second circuit boards 2 and the electronic components 8 as well as the electrical connection between the second circuit boards 3 and the electronic components 9 are maintained. Moreover, the electronic components 8 and 9 are fixed to the surface of the heat sink 12 facing the first circuit board 1, so that the electronic components 8 and 9 and the heat sink 12 are in thermal contact with each other. With this structure, the height levels of the electronic components 8 and 9 may be adjusted as desired through deformation of the second circuit boards 2 and 3 having flexibility. Thus, the thickness of the thermally conductive resin 14 may be substantially the same for each of the electronic components 8 and 9 regardless of their heights in the mounted state, and increase in the thickness of the thermally conductive resin 14 may be suppressed as well. Accordingly, the thermal conductivity of the thermally conductive resin 14 is not lowered, and the electronic components 8 and 9 may therefore be sufficiently cooled.

### Second Embodiment

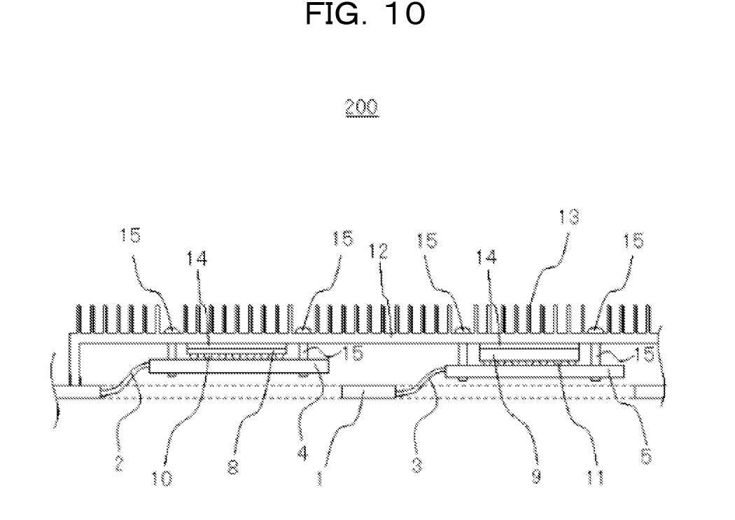

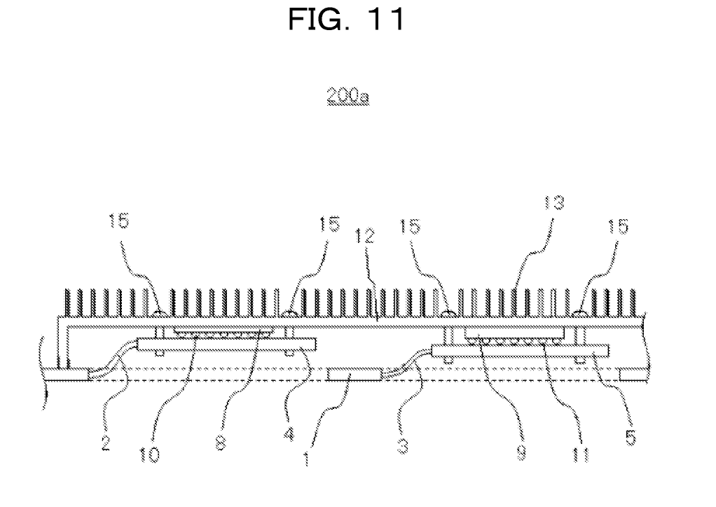

Next, a second embodiment is described with reference to FIGS. 10 and 11.

FIG. 10 is a diagram illustrating an example of an electronic device 200 in the second embodiment.

In the first embodiment, the electronic components 8 and 9 and the heat sink 12 are bonded by using only the thermally conductive resin 14. On the other hand, electronic components 8 and 9 in the second embodiment are fixed to a heat sink 12 mechanically by using screws 15 in addition to a thermally conductive resin 14.

As illustrated in FIG. 10, through-holes are provided in third circuit boards 4 and 5 and the heat sink 12. By inserting the screws 15 into the through-holes and fastening the screws 15, the electronic components 8 and 9 may be fixed to the heat sink 12. The material of the screws is stainless steel or plastic, for example.

By the mechanical fixing using the screws 15, it is possible to reduce tensile stress applied to the thermally conductive resin 14 by the gravitational force or the like on the electronic components 8 and 9 and the third circuit boards 4 and 5. Accordingly, it is possible to reduce bonding failure attributable to cracking, detachment, and the like. Nuts may be used as fastening members to fix the screws 15. Moreover, rivets may be used in place of the screws 15.

FIG. 11 is a diagram illustrating a modification of the electronic device 200 in the second embodiment. As illustrated in FIG. 11, in an electronic device 200a, the thermally conductive resin 14 is not used, and only the screws 15 are used to bring the electronic components 8 and 9 into thermal contact with the heat sink 12. In this way, supplying the thermally conductive resin 14 onto the electronic components 8 and 9 and curing the thermally conductive resin 14 are not desired. Accordingly, the manufacturing process may be simplified.

### Third Embodiment

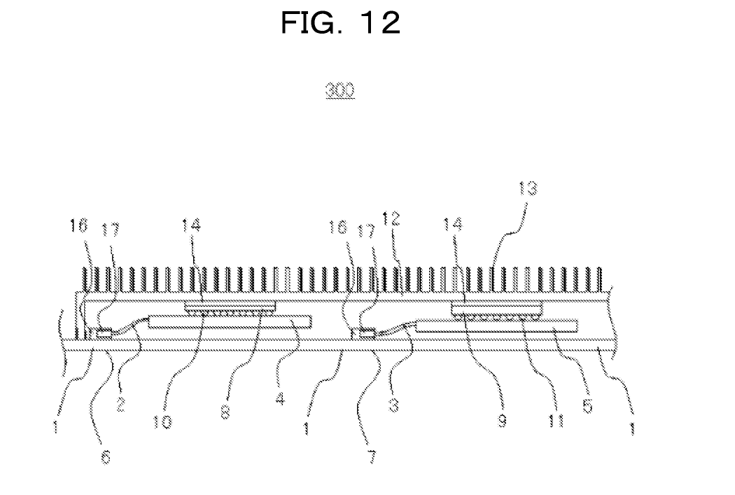

Next, a third embodiment is described with reference to FIGS. 12 to 16.

In the first embodiment, the rigid-flexible board in which the first circuit board 1, the second circuit boards 2 and 3, and the third circuit boards 4 and 5 are integrated is used. On the other hand, in the third embodiment, second circuit boards 2 and 3 and a first circuit board 1 are made attachable and detachable to and from each other by using connectors.

FIG. 12 is a structural view illustrating an example of an electronic device 300 in the third embodiment. As illustrated in FIG. 12, multiple first connectors 16 are disposed on a first circuit board 1. Each of second circuit boards 2 and 3 includes a second connector 17 at an end thereof. Moreover, each second connector 17 is inserted in an opening portion of the corresponding first connector 16, so that the first connector 16 and the second connector 17 are electrically connected to each other. The other features of the structure are substantially the same as those in the first embodiment illustrated in FIG. 2, and their description is therefore omitted.

Unlike the first embodiment, the openings 6 and 7 are not formed in the third embodiment. The connectors are used to make the second circuit boards 2 and 3 and the first circuit board 1 attachable and detachable to and from each other. In this way, openings are not desired in the first circuit board 1, and the package area may be increased accordingly. However, the openings 6 and 7 may be provided to facilitate fixing the electronic components 8 and 9 to the heat sink 12.

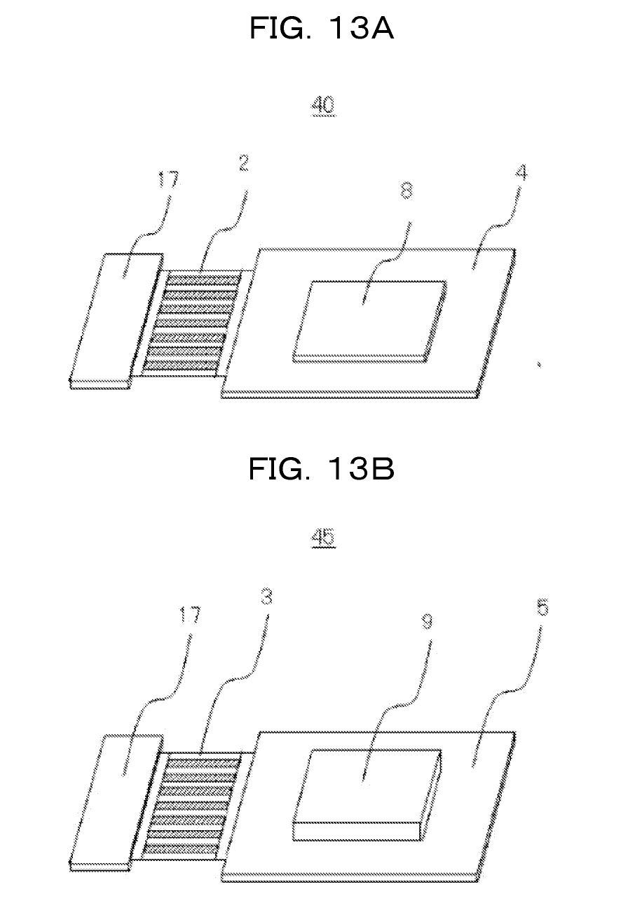

FIGS. 13A and 13B are perspective views illustrating an example of electronic component modules to be attached to the electronic device 300 in FIG. 12. As illustrated in FIG. 13A, an electronic component module 40 includes a second connector 17, a second circuit board 2, a third circuit board 4, and an electronic component 8. As in the first embodiment, the second circuit board 2 and the third circuit board 4 form a rigid-flexible board in which they are integrated. The second connector 17 is formed at the opposite end of the second circuit board 2 from the third circuit board 4. The second connector 17 functions as external connection terminals of the electronic component module 40. As illustrated in FIG. 13B, an electronic component module 45 on which is mounted an electronic component 9 thicker than the electronic component 8 includes a second connector 17, a second circuit board 3, and a third circuit board 5, and has substantially the same structure as that in FIG. 13A.

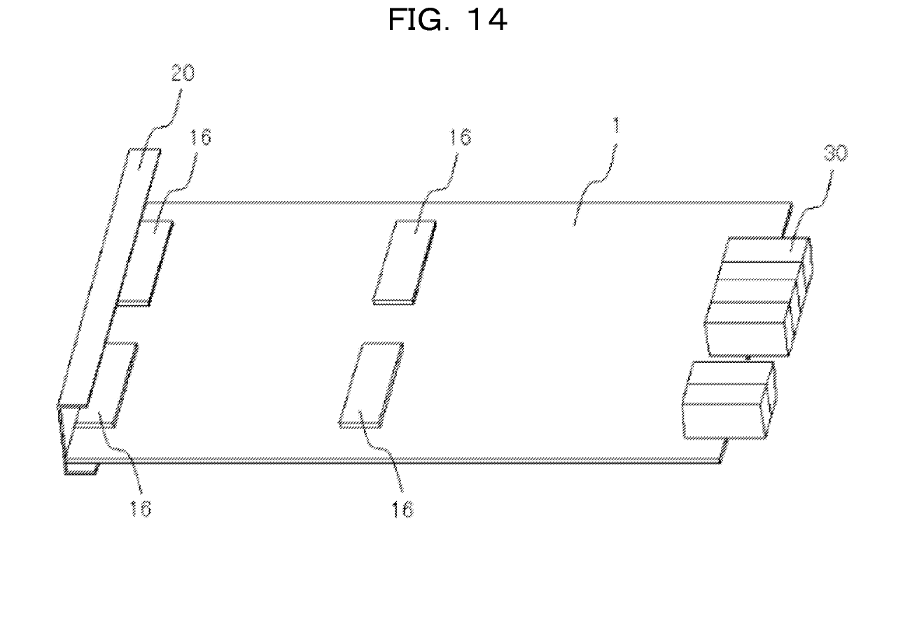

FIG. 14 is a perspective view illustrating a state of the electronic device 300 illustrated in FIG. 12 without the electronic component modules 40 and 45 mounted thereon. As illustrated in FIG. 14, the multiple first connectors 16 are disposed away from each other by predetermined distances on the first circuit board 1.

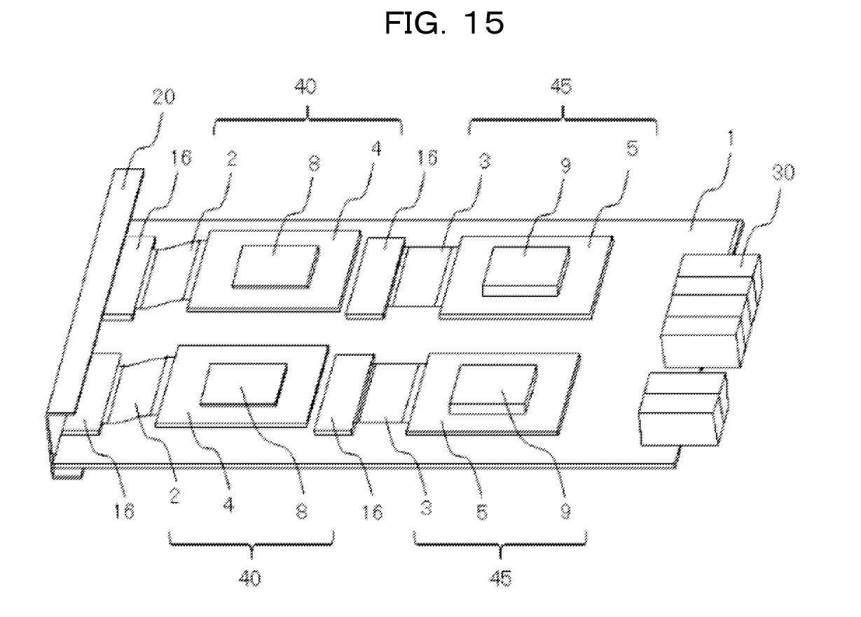

FIG. 15 is a perspective view illustrating a state of the electronic device 300 illustrated in FIG. 12 with the electronic component modules 40 and 45 mounted thereon. Two electronic component modules 40 are mounted on the left side of the first circuit board 1, and two electronic component modules 45 are mounted on the right side of the first circuit board 1. By connecting the second connectors 17 of the electronic component modules 40 and 45 illustrated in FIGS. 13A and 13B to the first connectors 16 on the first circuit board 1, the electronic component modules 40 and 45 may be disposed on the first circuit board 1 without interfering with each other as illustrated in FIG. 15.

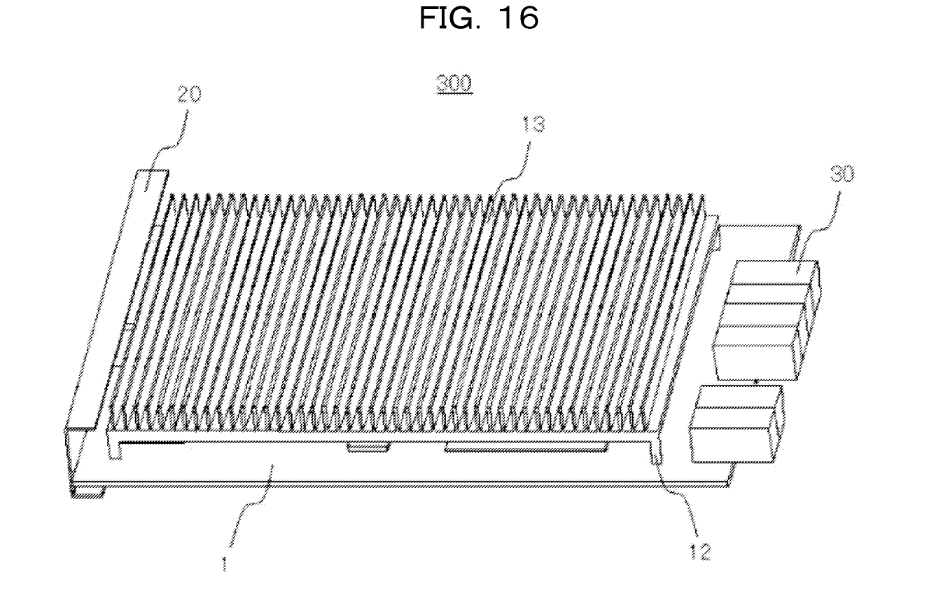

FIG. 16 is a perspective view illustrating a state of the electronic device 300 illustrated in FIG. 12 with the heat sink 12 mounted thereon. As illustrated in FIG. 16, the heat sink 12 covers the electronic components 8 and 9 (not illustrated) from above the first circuit board 1. As in the first or second embodiment, the heat sink 12 and the electronic components 8 and 9 may be bonded by using any one or both of a thermally conductive resin 14 and screws 15. In the case where no openings are provided in the first circuit board 1, the electronic components 8 and 9 and the heat sink 12 may be in thermal contact with each other by using a jig that may be inserted between the first circuit board 1 and the heat sink 12. Here, it is preferable to use the screws 15 alone as members to fix the electronic components 8 and 9 and the heat sink 12 to each other. The other features of the structure of the electronic device 300 are substantially the same as those of the electronic device 100 illustrated in FIG. 2, and their description is therefore omitted.

### Fourth Embodiment

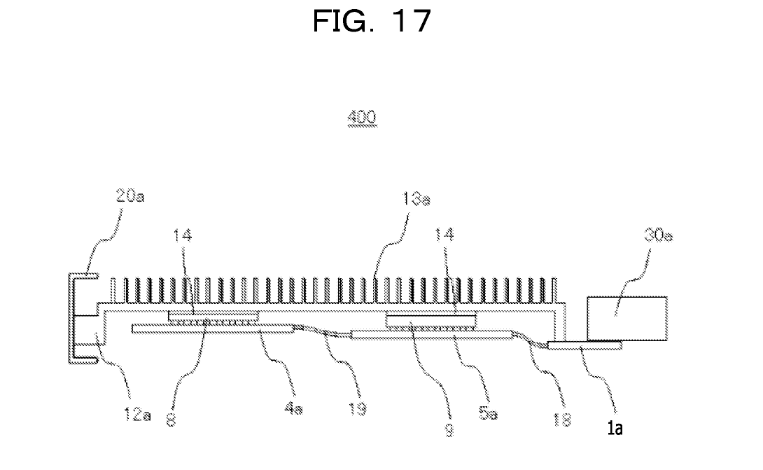

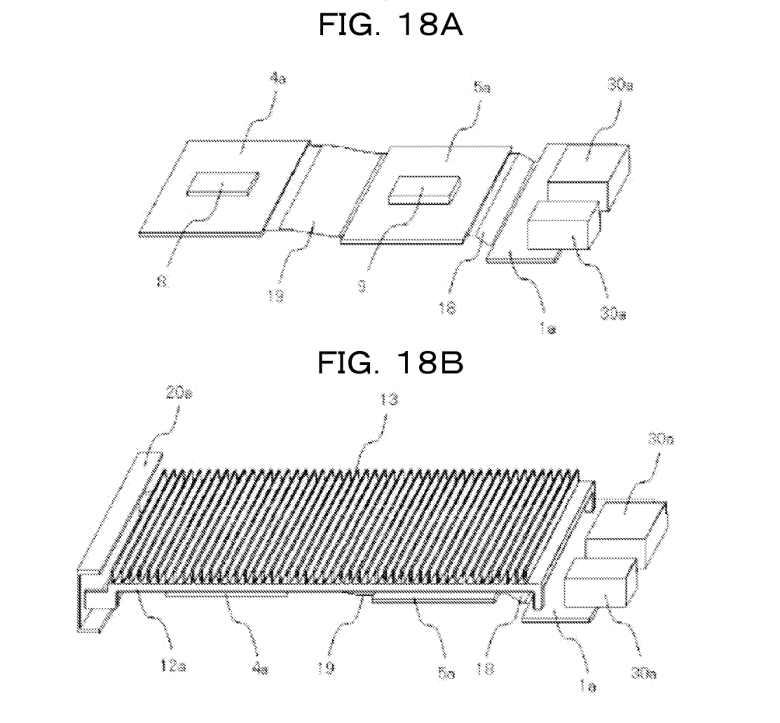

Next, a fourth embodiment is described with reference to FIGS. 17 and 18.

In the first embodiment, the third circuit boards 4 and 5 on which the electronic components 8 and 9 are mounted are electrically coupled to the first circuit board 1 by the second circuit boards 2 and 3, respectively. On the other hand, in the fourth embodiment, multiple circuit boards on which electronic components are mounted are coupled in series by a board having flexibility.

FIG. 17 is a structural view illustrating an example of an electronic device 400 in the fourth embodiment. FIG. 17, too, illustrates an example of the PIUs. As illustrated in FIG. 17, the electronic device 400 includes a first circuit board is and a fourth circuit board 18 having flexibility and electrically coupled to the first circuit board 1a. The electronic device 400 also includes a third circuit board 5a electrically coupled to the fourth circuit board 18, a fourth circuit board 19 having flexibility and electrically coupled to a third circuit board 4a, and the third circuit board 4a electrically coupled to the fourth circuit board 19.

Further, an electronic component 8 is mounted on the third circuit board 4a, and an electronic component 9 is mounted on the third circuit board 5a. Furthermore, a heat sink 12a is provided above the electronic components 8 and 9. Since the fourth circuit boards 18 and 19 have flexibility, the electronic components 8 and 9 may be bonded to the heat sink 12a by deforming the fourth circuit boards 18 and 19 even when the electronic components 8 and 9 have heights different from each other in the mounted state.

In this embodiment, the heat sink 12a is fixed to each of a face plate 20a and the first circuit board is with mechanical members such as screws. The first circuit board is includes connectors 30a for electrically connecting the electronic device 400 to the BWB.

FIGS. 18A and 18B are perspective views of the electronic device 400 illustrated in FIG. 17. FIG. 18A is a perspective view illustrating a state where the heat sink 12a is not mounted. The first circuit board 1a, the fourth circuit board 18, the third circuit board 5a, the fourth circuit board 19, and the third circuit board 4a form a rigid-flexible board in which they are integrated.

FIG. 18B is a perspective view illustrating a state of the electronic device 400 illustrated in FIG. 17 with the heat sink 12a mounted thereon. As illustrated in FIG. 18B, the heat sink 12a covers the electronic components 8 and 9 (not illustrated) from above the first circuit board 1a. For the method of bonding the electronic components 8 and 9 to the heat sink 12a, substantially the same method as any of those described so far may be used. Thus, detailed description of the method is omitted.

According to the fourth embodiment, the third circuit boards 4a and 5a and the first circuit board is are away from each other in plan view. Moreover, the back surfaces of the third circuit boards 4a and 5a, that is, the opposite surfaces of the third circuit boards 4a from the surfaces thereof on which the electronic components 8 and 9 are mounted, are exposed. By this structure, the pushing operation using a jig may be facilitated structurally. Accordingly, the electronic components 8 and 9 and the heat sink 12a may be bonded easily.

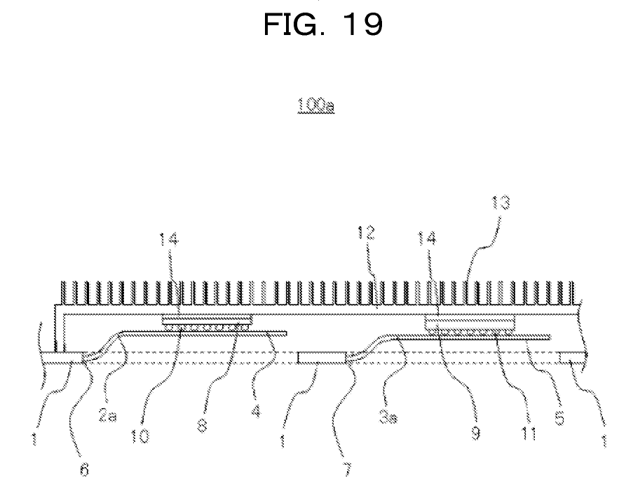

Although the preferred embodiments are described above in detail, embodiments are not limited to the specific embodiments, and various changes and alterations may be made. For example, in embodiments described hereinabove, instances where the electronic components 8 and 9 are mounted on the third circuit boards 4 and 5 are discussed, but embodiments are not limited to these embodiments. FIG. 19 is a diagram illustrating a modification of the electronic device 100 in the first embodiment. As illustrated in FIG. 19, the electronic component 8 included in an electronic device 100a is coupled to a second circuit board 2a by the solder bumps 10. The electronic component 9 is coupled to a second circuit board 3a by the solder bumps 11. As described above, the electronic components 8 and 9 may be mounted directly on the second circuit boards 2a and 3a without using the third circuit boards 4 and 5, respectively.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device, comprising:
a first circuit board;
a heat sink fixed to the first circuit board to form a cavity between the heat sink and the first circuit board; and
a plurality of electronic components fixed to a surface of the heat sink facing the first circuit board inside the cavity, the plurality of electric components having heights different from each other,
wherein each of the plurality of electronic components is electrically coupled to the first circuit board by a second circuit board being capable of bending and being different from the first circuit board.

2. The electronic device according to claim 1,
wherein the first circuit board includes an opening at each of positions facing the plurality of electronic components.

3. The electronic device according to claim 2,
wherein the second circuit board extends from an inner wall of the opening, the inner wall being a section of the first circuit board, and
a wiring layer of the second circuit board is integrally buried in the first circuit board.

4. The electronic device according to claim 1,
wherein the plurality of electronic components are bonded to the heat sink with a thermally conductive resin interposed therebetween.

5. The electronic device according to claim 1,
wherein the plurality of electronic components are disposed away from each other in plan view seen from a direction of the heat sink.

6. The electronic device according to claim 1, further comprising:
a plurality of third circuit boards on which the plurality of electronic devices are individually disposed,
wherein a clearance is left between each of the plurality of third circuit boards and the first circuit board.

7. The electronic device according to claim 6,
wherein the plurality of third circuit boards are disposed such that the third circuit boards do not overlap the first circuit board in plan view seen from a direction of the heat sink.

8. The electronic device according to claim 6,
wherein a wiring layer of the second circuit board is integrally buried in the corresponding third circuit board.

9. The electronic device according to claim 1,
wherein each of a plurality of third circuit boards, the corresponding second circuit board, and the first circuit board are coupled in series.

10. An electronic apparatus, comprising:
a casing; and
at least one electronic device housed in the casing and comprising:
a first circuit board;
a heat sink fixed to the first circuit board to form a cavity between the heat sink and the first circuit board; and
a plurality of electronic components fixed to a surface of the heat sink facing the first circuit board inside the cavity, the plurality of electric components having heights different from each other,
wherein each of the plurality of electronic components is electrically coupled to the first circuit board by a second circuit board being capable of bending and being different from the first circuit board.

11. A method for manufacturing an electronic device, the method comprising:
coupling a first circuit board and a plurality of electronic components to each other with a plurality of second circuit boards being capable of bending and being different from the first circuit board, the plurality of electronic components having heights different from each other;
fixing a heat sink to the first circuit board to form a cavity between the heat sink and the first circuit board; and
fixing, inside the cavity, the plurality of electronic components to a surface of the heat sink facing the first circuit board by moving the plurality of electronic components upward from the first circuit board.

12. The method according to claim 11,
wherein the fixing the plurality of electronic components includes moving the plurality of electronic components upward from the first circuit board by pushing the plurality of electronic components with a jig inserted in openings provided in the first circuit board at positions facing the plurality of electronic components.
